(19) United States
(12) Patent Application Publication
(10) Pub. No.: US 2008/0265954 A1
(43) Pub. Date: Oct. 30, 2008

(54) Reduced Transition Time Ramp Waveform Generator

(76) Inventor: Alan J. DeVilbiss, Colorado Springs, CO (US)

Correspondence Address: HANES & SCHUTZ, LLC, 102 SOUTH TEJON ST., SUITE 800, COLORADO SPRINGS, CO, 80903, US

(21) Appl. No.: 11/740,423

(22) Filed: Apr. 26, 2007

(51) Int. Cl. H03K 4/90

(52) U.S. Cl. 327/133

(57) ABSTRACT

A system and method for generating a reduced transition time ramp waveform signal are disclosed. Two offset, synchronized ramp waveform signals are generated. Each ramp waveform signal has a repeating sequence including a linear development segment, an upper transition segment, a return segment, and a lower transition segment. The ramp waveform signals are offset synchronized such that the linear development segment of each ramp waveform signal begins before the linear development segment of the other ramp waveform signal ends. Each ramp waveform signal is sampled during its linear development segment to generate a reduced transition time ramp waveform signal.

### BACKGROUND OF THE INVENTION

A signal generator, or function generator, is an apparatus that generates repeating waveform signals. Often signal generators have several built in types of waveform signals that they are able to generate. One of these types of signals is usually a ramp, or saw tooth, waveform.

### DESCRIPTION OF THE DRAWINGS

FIG. 1 is a block diagram of one embodiment of the reduced transition time ramp waveform generator of the present invention.

FIG. 2 is a diagram illustrating a ramp signal generated by the ramp waveform signal generators of FIG. 1

FIG. 3 is a flow chart illustrating one embodiment of the method of the present invention for generating a pulse stream.

FIG. 4 is a timing diagram illustrating the method of the present invention.

### DETAILED DESCRIPTION OF THE INVENTION

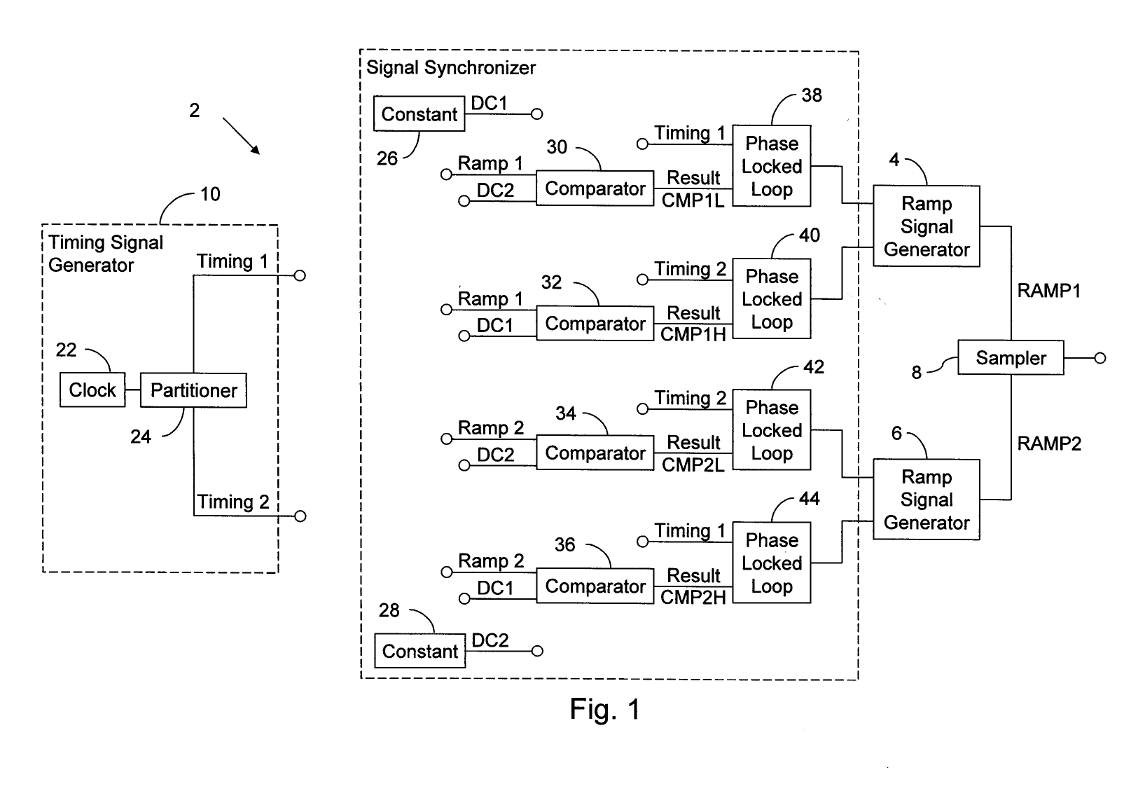

FIG. 1 illustrates one embodiment of the reduced transition time ramp waveform generator 2 of the present invention. In this embodiment, reduced transition time ramp waveform generator 2 includes ramp waveform signal generators 4, 6, sampler 8, timing signal generator 10, and signal synchronizer 12.

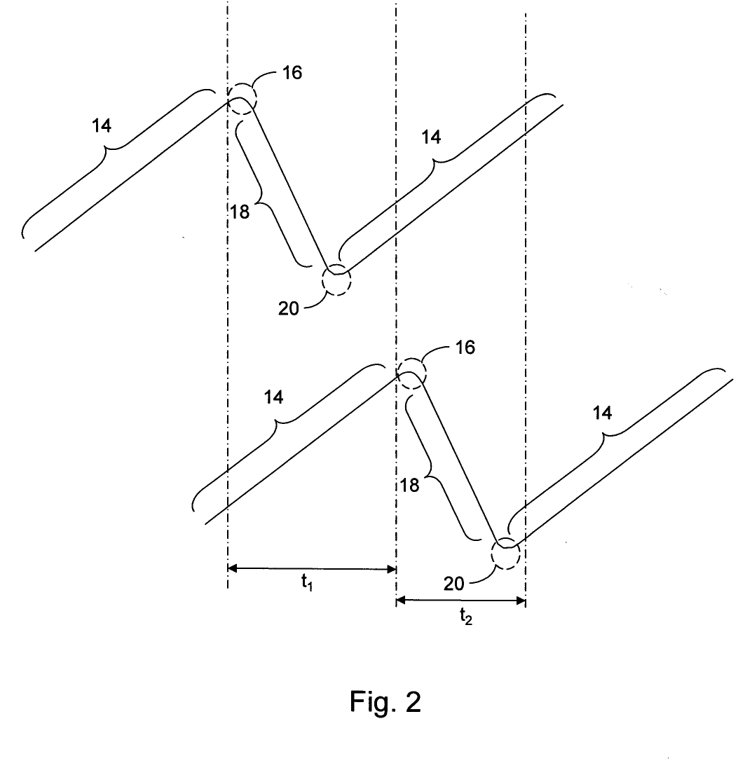

Ramp waveform signal generators 4, 6 generate ramp waveform signals. FIG. 2 illustrates the ramp waveforms, Ramp 1 and Ramp 2, generated by ramp waveform signal generators 4, 6. Each ramp waveform signal, Ramp 1 and Ramp 2, has a repeating sequence including a linear development segment 14, an upper transition segment 16, a return segment 18, and a lower transition segment 20. In this example, linear development segment 14 is a rising segment and the return segment 18 is a falling segment. Alternatively, linear development segment 14 may be a falling segment and the return segment 18 may be a rising segment.

The ramp waveform signals Ramp 1, Ramp 2 are offset synchronized such that the linear development segment 14 of the second ramp waveform signal, Ramp 2, begins before the linear development segment 14 of the first ramp waveform signal, Ramp 1, ends and the linear development segment 14 of the first ramp waveform signal, Ramp 1, begins before the linear development segment 14 of the second ramp waveform signal, Ramp 2, ends. The offset synchronization of first and second ramp waveform signals, Ramp 1 and Ramp 2, may be further defined so that the upper 16 and lower 20 transition segments and the return segment 18 of the first ramp waveform signal, Ramp 1, occurs during the linear development segment 14 of the second ramp waveform signal, Ramp 2, and the upper 16 and lower 20 transition segments and the return segment 18 of the second ramp waveform signal, Ramp 2, occurs during the linear development segment 14 of the first ramp waveform signal, Ramp 1.

Sampler 8 is any means for sampling each ramp waveform signal Ramp 1, Ramp 2, during its linear development segment 14 to generate a reduced transition time ramp waveform signal.

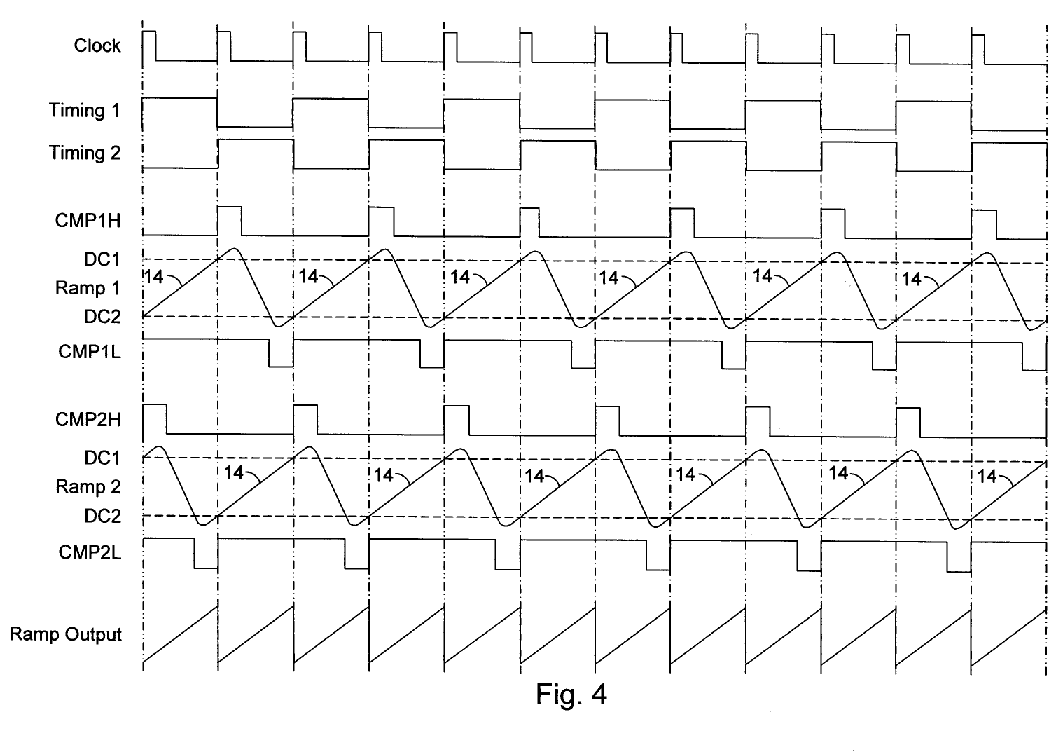

Timing signal generator 10 is any apparatus or system configured to generate timing signals, Timing 1 and Timing 2. The timing signals, Timing 1 and Timing 2, are synchronized to have states opposite to one another (see FIG. 4). In one embodiment, timing signal generator 10 includes clock 22 and partitioner 24.

Clock 22 is any combination of hardware and executable code configured to generate a clock signal (see FIG. 4). Partitioner 24 is any combination of hardware and executable code configured to derive the timing signals, Timing 1 and Timing 2, from the clock signal. Each of the timing signals, Timing 1 and Timing 2, is one half the frequency of the clock signal. Each of the timing signals, Timing 1 and Timing 2, changes state on the positive edge of the clock signal. The state changes of each timing signal moving in opposite directions to the state changes of the other timing signal (see FIG. 4).

Signal synchronizer 12 is any apparatus or system configured to synchronize the ramp waveform signals, Ramp 1 and Ramp 2, to the timing signals, Timing 1 and Timing 2. In one embodiment, the signal synchronizer includes constant voltage signal generators 26, 28 comparators 30, 32, 34, 36, and phase locked loops 38, 40, 42, 44.

Constant voltage signal generators 26, 28 generate constant voltage signals, DC1 and DC2, offset in amplitude from one another (see FIG. 4). The voltages may be any voltage suitable for indicating the top and bottom of the linear development segments of the ramp waveform signals, Ramp 1 and Ramp 2.

The comparators are any combination of hardware and executable code configured to compare the ramp waveform signals, Ramp 1 and Ramp 2, to the constant voltage signals, DC1 and DC2, to produce result signals. When the ramp waveform signal, Ramp 1, is higher than the constant voltage signal DC1, the comparator 30, produces a high signal, otherwise it produces a low signal. When ramp signal, Ramp 1, is greater than constant voltage signal, DC2, comparator 32 produces a high signal, otherwise it produces a low signal. When ramp signal, Ramp 2, is higher than constant voltage signal, DC1, comparator 34 produces a high signal, otherwise it produces a low signal. When ramp signal, Ramp 2, is greater than constant voltage signal, DC2, comparator 36 produces a high signal, otherwise it produces a low signal.

The details of phase locked loops are well known and will not be discussed in this disclosure. The phase locked loops 38, 40, 42, 44 are any apparatus or system configured to control the synchronization and timing of ramp signal generators 4, 6. In one embodiment, phase locked loop 38 is configured to control the repetition frequency and phase of ramp signal, Ramp 1, such that each positive transition of the result signal CMP1H of comparator 30 occurs in time alignment with a positive transition of the timing signal, Timing 1. Phase locked loop 42 is configured to control the repetition frequency and phase of ramp signal, Ramp 2, such that each positive transition of the result signal CMP2H of comparator 34 occurs in time alignment with a positive transition of the timing signal, Timing 2. Phase locked loop 40 is configured to control the rate of change, or slope, of the linear development segment 14 of ramp signal, Ramp 1, such that each positive transition of the result signal CMP1L of comparator 32 occurs in time alignment with a positive transition of the timing signal Timing 2. Phase locked loop 44 is configured to control the rate of change, or slope, of the linear development segment of ramp signal, Ramp 2, such that each positive transition of the result signal CMP2L of comparator 36 occurs in time alignment with a positive transition of the timing signal, Timing 1.

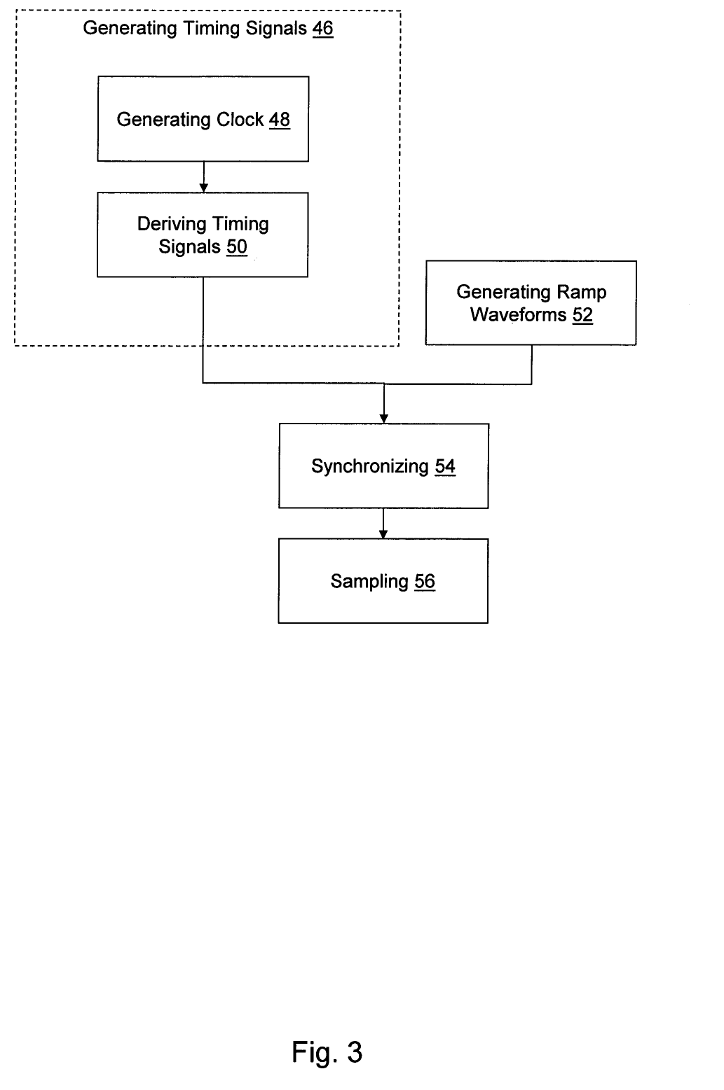

FIG. 3 is a flow chart representing steps of one embodiment of the present invention. Although the steps represented in FIG. 3 are presented in a specific order, the present invention encompasses variations in the order of steps. Furthermore, additional steps may be executed between the steps illustrated in FIG. 3 without departing from the scope of the present invention. An understanding of FIG. 3 is enhanced by viewing it in combination with FIG. 4.

In one embodiment, timing signals, Timing 1 and Timing 2, are generated 46. In one embodiment, timing signals, Timing 1 and Timing 2, are generated 46 by generating 48 a clock signal and deriving 50 the timing signals, Timing 1 and Timing 2, from the clock signal.

Ramp waveform signals, Ramp 1 and Ramp 2, are generated 52. Each ramp waveform signal Ramp 1 and Ramp 2, has a repeating sequence including a linear development segment 14, an upper transition segment 16, a return segment 18, and a lower transition segment 20. The ramp waveform signals, Ramp 1 and Ramp 2, are offset synchronized such that the linear development segment 14 of each ramp waveform signal begins before the linear development segment 14 of the other ramp waveform signal ends.

In one embodiment, the ramp waveform signals, Ramp 1 and Ramp 2, are synchronized to the timing signals, Timing 1 and Timing 2. In one embodiment, synchronizing the ramp signals, Ramp 1 and Ramp 2 to the timing signals timing 1 and Timing 2 includes generating constant voltage signals, DC1 and DC2, offset in amplitude from one another. Ramp waveform signals, Ramp 1 and Ramp 2, are compared to the constant voltage signals, DC1 and DC2, to produce result signals. When ramp waveform signal, Ramp 1, is higher than constant voltage signal, DC1, the first result signal, CMP1H, is high, otherwise it is low. When ramp waveform signal, Ramp 1, is greater than constant voltage signal, DC2, the second result signal, CMP1L, is high, otherwise it is low. When ramp waveform signal, Ramp 2, is higher than constant voltage signal, DC1, the third result signal, CMP2H, is high, otherwise it is low. When ramp waveform signal, Ramp 2, is greater than constant voltage signal, DC2, the fourth result signal, CMP2L, is high, otherwise it is low.

A repetition frequency and phase of ramp waveform signal, Ramp 1, is controlled such that each positive transition of the second result signal, CMP1L, occurs in time alignment with a positive transition of timing signal, Timing 1. A repetition frequency and phase of ramp waveform signal, Ramp 2, is controlled such that each positive transition of the fourth result signal, CMP2L, occurs in time alignment with a positive transition of timing signal, Timing 2. A rate of change, or slope, of the linear development segment 14 of ramp waveform signal, Ramp 1, is controlled such that each positive transition of the first result signal, CMP1H, occurs in time alignment with a positive transition of timing signal, Timing 2. A rate of change, or slope, of the linear development segment 14 of ramp waveform signal, Ramp 2, is controlled such that each positive transition of the third result signal, CMP2H, occurs in time alignment with a positive transition of timing signal, Timing 1.

Each ramp waveform signal, Ramp 1 and Ramp 2, is sampled 56 during its linear development segment 14 to generate a reduced transition time ramp waveform signal, Ramp Output.

The foregoing description is only illustrative of the invention. Various alternatives, modifications, and variances can be devised by those skilled in the art without departing from the invention. Accordingly, the present invention embraces all such alternatives, modifications, and variances that fall within the scope of the described invention.

What is claimed is:

1. A method for generating a reduced transition time ramp waveform signal, the method comprising:
generating first and second offset, synchronized ramp waveform signals, each ramp waveform signal having a repeating sequence including a linear development segment, an upper transition segment, a return segment, and a lower transition segment, the first and second ramp waveform signals offset synchronized such that the linear development segment of the second ramp waveform signal begins before the linear development segment of the first ramp waveform signal ends and the linear development segment of the first ramp waveform signal begins before the linear development segment of the second ramp waveform signal ends and
sampling each ramp waveform signal during its linear development segment to generate a reduced transition time ramp waveform signal.

2. The method of claim 1 wherein the first and second ramp waveform signals are further offset synchronized such that the upper and lower transition segments and the return segment of the first ramp waveform signal occurs during the linear development segment of the second ramp waveform signal and the upper and lower transition segments and the return segment of the second ramp waveform signal occurs during the linear development segment of the first ramp waveform signal.

3. The method of claim 1 further including:
generating a first timing signal;
generating a second timing signal synchronized to have states opposite to the states of the first timing signal; and
synchronizing the first and second ramp waveform signals to the first and second timing signals.

4. The method of claim 3 wherein generating the first and second timing signals includes:
generating a clock signal and
deriving the first and second timing signals from the clock signal wherein each of the first and second timing signals is one half the frequency of the clock signal, each changing state on the positive edge of the clock signal, the state changes of the second timing signal moving in opposite directions to the state changes of the first timing signal.

5. The method of claim 3 wherein synchronizing the first and second ramp waveform signals to the first and second timing signals includes:
generating first and second constant voltage signals offset in amplitude from one another;
comparing the first and second ramp waveform signals to the first and second constant voltage signals to produce first, second, third, and fourth result signals such that when the first ramp waveform signal is higher than the first constant voltage signal, the first result signal is high, otherwise it is low; when the first ramp waveform signal is greater than the second constant voltage signal, the second result signal is high, otherwise it is low; when the second ramp waveform signal is higher than the first constant voltage signal, the third result signal is high, otherwise it is low; and when the second ramp waveform signal is greater than the second constant voltage signal, the fourth result signal is high, otherwise it is low;
controlling a repetition frequency and phase of the first ramp waveform signal such that each positive transition of the second result signal occurs in time alignment with a positive transition of the first timing signal;
controlling a repetition frequency and phase of the second ramp waveform signal such that each positive transition of the fourth result signal occurs in time alignment with a positive transition of the second timing signal;
controlling a rate of change of the linear development segment of the first ramp waveform signal such that each positive transition of the first result signal occurs in time alignment with a positive transition of the second timing signal; and
controlling a rate of change of the linear development segment of the second ramp waveform signal such that each positive transition of the third result signal occurs in time alignment with a positive transition of the first timing signal.

6. A reduced transition time ramp waveform signal generator comprising:
a first ramp waveform signal generator for generating a first ramp waveform signal;
a second ramp waveform signal generator for generating a second ramp, each ramp waveform signal having a repeating sequence including a linear development segment, an upper transition segment, a return segment, and a lower transition segment, the first and second ramp waveform signals offset synchronized such that the linear development segment of the second ramp waveform signal begins before the linear development segment of the first ramp waveform signal ends and the linear development segment of the first ramp waveform signal begins before the linear development segment of the second ramp waveform signal ends and
means for sampling each ramp waveform signal during its linear development segment to generate a reduced transition time ramp waveform signal.

7. The ramp waveform signal generator of claim 6 wherein the first and second ramp waveform signals are further offset synchronized such that the upper and lower transition segments and the return segment of the first ramp waveform signal occurs during the linear development segment of the second ramp waveform signal and the upper and lower transition segments and the return segment of the second ramp waveform signal occurs during the linear development segment of the first ramp waveform signal.

8. The ramp waveform signal generator of claim 6 further including:
a timing signal generator configured to generate first and second timing signals, the second timing signal synchronized to have states opposite to the states of the first timing signal; and
a signal synchronizer configured to synchronize the first and second ramp waveform signals to the first and second timing signals.

9. The ramp waveform signal generator of claim 8 wherein the timing signal generator includes:
a clock configured to generate a clock signal and
a partitioner configured to derive the first and second timing signals from the clock signal wherein each of the first and second timing signals is one half the frequency of the clock signal, each changing state on the positive edge of the clock signal, the state changes of the second timing signal moving in opposite directions to the state changes of the first timing signal.

10. The ramp waveform signal generator of claim 8 wherein the signal synchronizer includes:
first and second constant voltage signal generators for generating first and second constant voltage signals offset in amplitude from one another;
first, second, third, and fourth comparators configured to compare the first and second ramp waveform signals to the first and second constant voltage signals to produce first, second, third, and fourth result signals such that when the first ramp waveform signal is higher than the first constant voltage signal, the first comparator produces a high signal, otherwise the first comparator produces a low signal; when the first ramp waveform signal is greater than the second constant voltage signal, the second comparator produces a high signal, otherwise the second comparator produces a low signal; when the second ramp waveform signal is higher than the first constant voltage signal, the third comparator produces a high signal, otherwise the third comparator produces a low signal; and when the second ramp waveform signal is greater than the second constant voltage signal, the fourth comparator produces a high signal, otherwise the fourth comparator produces a low signal;
a first phase locked loop configured to control a repetition frequency and phase of the first ramp waveform signal such that each positive transition of the second result signal occurs in time alignment with a positive transition of the first timing signal;
a second phase locked loop configured to control a repetition frequency and phase of the second ramp waveform signal such that each positive transition of the fourth result signal occurs in time alignment with a positive transition of the second timing signal;
a third phase locked loop configured to control a rate of change of the linear development segment of the first ramp waveform signal such that each positive transition of the first result signal occurs in time alignment with a positive transition of the second timing signal; and
a fourth phase locked loop configured to control a rate of change of the linear development segment of the second ramp waveform signal such that each positive transition of the third result signal occurs in time alignment with a positive transition of the first timing signal.
